(19) United States
(12) Patent Application Publication
(10) Pub. No.: US 2019/0341499 A1
(43) Pub. Date: Nov. 7, 2019

(54) TFT, MANUFACTURING METHOD THEREOF, AND LCD DEVICE

(71) Applicant: Shenzhen China Star Optoelectronics Semiconductor Display Technology Co., Ltd, Shenzhen, Guangdong (CN)

(72) Inventor: Wei WU, Shenzhen, Guangdong (CN)

(21) Appl. No.: 16/079,396

(22) PCT Filed: Nov. 25, 2017
(86) PCT No.: PCT/CN2017/112980

§ 371 Date: Aug. 23, 2018

(30) Foreign Application Priority Data
Nov. 9, 2017 (CN) 201711103257.X

(51) Int. Cl. H01L 29/786; H01L 29/66; H01L 29/22; H01L 27/12; G02F 1/1368; H01L 29/417

(52) U.S. Cl. CPC H01L 29/78618; H01L 29/66742; H01L 29/2206; H01L 29/41733; H01L 27/1218; H01L 27/1225; G02F 1/1368; H01L 29/78669

(57) ABSTRACT

The TFT includes a substrate, a gate electrode, a gate insulation layer, an active layer, a source electrode, and a drain electrode. The gate electrode has a first lateral surface and a second lateral surface opposite to each other. The gate electrode is disposed on the substrate. The gate insulation layer covers the gate electrode. The active layer is disposed on the gate insulation layer, and has a first lateral surface and a second lateral surface opposite to each other. The source electrode is disposed adjacent to the first lateral surface of the active layer. The source electrode and the first lateral surface of the gate electrode are co-planar or have a first lateral gap. The drain electrode is disposed adjacent to the second lateral surface of the active layer. The drain electrode and the second lateral surface of the gate electrode are co-planar or have a second lateral gap.

### CROSS-REFERENCE TO RELATED APPLICATIONS

This application claims priority to Chinese Patent Application No. 201711103257.X, filed on Nov. 9, 2017, the disclosure of which is incorporated herein by reference in its entirety.

### FIELD OF THE INVENTION

The present invention is generally related to the manufacturing method of thin film transistor (TFT), and more particularly to a TFT, its manufacturing method, and a liquid crystal display (LCD) device.

### BACKGROUND OF THE INVENTION

LCD devices are gaining popularity, due to its low power consumption, small form factor, and low radiation. A LCD device usually includes an array substrate, a color filter (CF) substrate, and a liquid crystal layer. The array substrate and the CF substrate are disposed oppositely at a distance to form an accommodation space. The liquid crystal layer is disposed in the accommodation space between the array and CF substrates. The array substrate includes thin film transistors (TFTs) arranged in an array. A TFT includes a gate, a source, and a drain. For a conventional TFT, there is overlapping between the gate and source, and between the gate and drain. Therefore, parasitic capacitances are introduced between the gate and source, and between the gate and drain. Parasitic capacitance may deteriorate TFT function. As the display panels become larger with higher resolution and frequency, the impact of the parasitic capacitance become more serious.

### SUMMARY OF THE INVENTION

The present invention teaches a thin film transistor (TFT) including a substrate, a gate electrode, a gate insulation layer, an active layer, a source electrode, and a drain electrode. The substrate has a first surface and a second surface opposite to each other. The gate electrode has a first lateral surface and a second lateral surface opposite to each other. The gate electrode is disposed on the first surface of the substrate, and the first and second lateral surfaces intersect the first surface. The gate insulation layer covers the gate electrode. The active layer is disposed on a surface of the gate insulation layer away from the gate electrode. The active layer has a first lateral surface and a second lateral surface opposite to each other. The source electrode is disposed adjacent to the first lateral surface of the active layer, and is electrically connected to the active layer through its first lateral surface. The source electrode and the first lateral surface of the gate electrode are co-planar or have a first lateral gap in between. The drain electrode is disposed adjacent to the second lateral surface of the active layer, and is electrically connected to the active layer through its second lateral surface. The drain electrode and the second lateral surface of the gate electrode are co-planar or have a second lateral gap in between. The active layer is a metal oxide semiconductor layer.

Compared to the prior art, the TFT of the present invention arranges the source electrode to have a first lateral gap from or to be co-planar with the first lateral surface of the gate electrode, and arranges the drain electrode to have a second lateral gap from or to be co-planar with the second lateral surface of the gate electrode. Then the source electrode is not overlapped with the gate electrode, and the drain electrode is not overlapped with the gate electrode. The parasitic capacitance between the source electrode and the gate electrode, and between the drain electrode and the gate electrode is effectively reduced.

The present invention also teaches a TFT manufacturing method including the following steps.

Providing a substrate having a first surface and a second surface opposite to each other.

Forming a gate electrode on the first surface, where the gate electrode has a first lateral surface and a second lateral surface opposite to each other, and the first and second lateral surfaces intersect the first surface.

Forming a gate insulation layer covering the gate electrode.

Forming an active layer on the gate insulation layer, where the active layer has a first lateral surface and a second lateral surface opposite to each other, and the active layer is a metal oxide semiconductor layer.

Forming a source electrode and a drain electrode, where the source electrode is disposed adjacent to the first lateral surface of the active layer, and is electrically connected to the active layer through its first lateral surface, the source electrode and the first lateral surface of the gate electrode are co-planar or have a first lateral gap in between, the drain electrode is disposed adjacent to the second lateral surface of the active layer, and is electrically connected to the active layer through its second lateral surface, and the drain electrode and the second lateral surface of the gate electrode are co-planar or have a second lateral gap in between.

The present invention also teaches a LCD device, including a TFT as described above.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a structural schematic diagram showing a thin film transistor (TFT) according to a first embodiment of the present invention.

FIG. 2 is a structural schematic diagram showing a TFT according to a second embodiment of the present invention.

FIG. 3 is a flow diagram showing a TFT manufacturing method according to an embodiment of the present invention.

FIGS. 4 to 8 depict the manufacturing of a TFT by the steps of the TFT manufacturing method of FIG. 3.

FIG. 9 is a flow diagram showing additional steps of the TFT manufacturing method of FIG. 3.

FIGS. 10 and 11 depict the manufacturing of a TFT by the steps of the TFT manufacturing method of FIG. 9.

FIG. 12 is a flow diagram showing additional steps of the TFT manufacturing method of FIG. 3.

FIG. 13 depicts the manufacturing of a TFT by the step of the TFT manufacturing method of FIG. 12.

FIG. 14 is a flow diagram showing additional steps of the TFT manufacturing method of FIG. 3.

FIGS. 15 and 16 depict the manufacturing of a TFT by the steps of the TFT manufacturing method of FIG. 14.

FIG. 17 is a flow diagram showing additional steps of the TFT manufacturing method of FIG. 3.

FIG. 18 is a flow diagram showing additional steps of the TFT manufacturing method of FIG. 3.

FIG. 19 is a schematic diagram showing a LCD device according to an embodiment of the present invention.

### DETAILED DESCRIPTION OF PREFERRED EMBODIMENTS

The following descriptions for the respective embodiments are specific embodiments capable of being implemented for illustrations of the present invention with referring to appended figures.

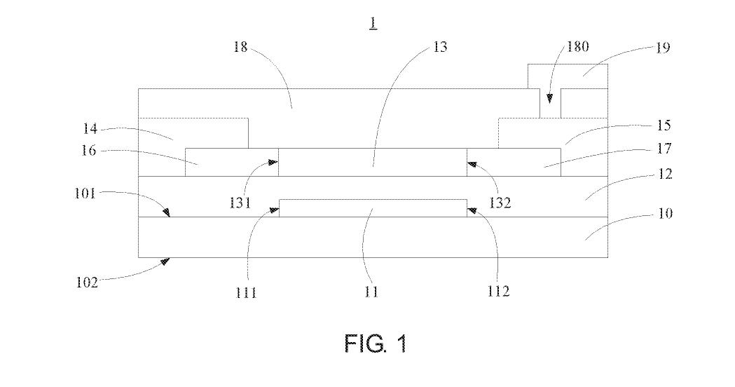

FIG. 1 is a structural schematic diagram showing a thin film transistor (TFT) according to a first embodiment of the present invention. The TFT 1 includes a substrate 10, a gate electrode 11, a gate insulation layer 12, an active layer 13, a source electrode 14, and a drain electrode 15. The substrate 10 has a first surface 101 and a second surface 102 opposite to each other. The gate electrode 11 has a first lateral surface 111 and a second lateral surface 112 opposite to each other. The gate electrode 11 is disposed on the first surface 101 of the substrate 10, and the first and second lateral surfaces 111 and 112 intersect the first surface 101. The gate insulation layer 12 covers the gate electrode 11. The active layer 13 is disposed on a surface of the gate insulation layer 12 away from the gate electrode 11. The active layer 13 has a first lateral surface 131 and a second lateral surface 132 opposite to each other. The source electrode 14 is disposed adjacent to the first lateral surface 131 of the active layer 13, and is electrically connected to the active layer 13 through its first lateral surface 131. The source electrode 14 and the first lateral surface 111 are co-planar or, as shown in FIG. 1, have a first lateral gap in between. The drain electrode 15 is disposed adjacent to the second lateral surface 132 of the active layer 13, and is electrically connected to the active layer 13 through its second lateral surface 132. The drain electrode 15 and the second lateral surface 112 are co-planar or, as shown in FIG. 1, have a second lateral gap in between. The active layer 13 is a metal oxide semiconductor layer.

The substrate 10 is a transparent substrate, such as a glass substrate, a plastic substrate, etc. The substrate 10 may also be a flexible substrate.

The active layer 13 is a metal oxide semiconductor layer. For example, the active layer 13 is an indium gallium zinc oxide (IGZO) layer but the present invention is not limited as such.

The source electrode 14 and the first lateral surface 111 are co-planar or have a first lateral gap in between. Preferably, the source electrode 14 and the first lateral surface 111 are arranged to have the first lateral gap in between. Selectively, the source electrode 14 and the first lateral surface 111 are arranged to be co-planar. It is understandable that, considering manufacturing tolerance, the source electrode 14 and the first lateral surface 111 are considered co-planar even though they are slightly offset or overlapped within a certain degree of precision without deviating the present invention's intention.

Similarly, the drain electrode 15 and the second lateral surface 112 are co-planar or have a second lateral gap in between. Preferably, the drain electrode 15 and the second lateral surface 112 are arranged to have the second lateral gap in between. Selectively, the drain electrode 15 and the second lateral surface 112 are arranged to be co-planar. It is understandable that, considering manufacturing tolerance, the drain electrode 15 and the second lateral surface 112 are considered co-planar even though they are slightly offset or overlapped within a certain degree of precision without deviating the present invention's intention.

With the source electrode 14 and the first lateral surface 111 being co-planar or having the first lateral gap in between, and the drain electrode 15 and the second lateral surface 112 being co-planar or having the second lateral gap in between, there would be no overlapping between the gate electrode 11 and the source electrode 14, and between the gate electrode 11 and the drain electrode 15 of the TFT 1 of the present invention, thereby reducing the parasitic capacitance between the gate and source electrodes 11 and 14, and between the gate and drain electrodes 11 and 15.

Preferably, the first lateral surfaces 131 and 111 of the active layer 13 and the gate electrode 11 are co-planar, and the second lateral surfaces 132 and 112 of the active layer 13 and the gate electrode 11 are co-planar.

It is understandable that, considering manufacturing tolerance, the first lateral surfaces 131 and 111 of the active layer 13 and the gate electrode 11, and the second lateral surfaces 132 and 112 of the active layer 13 and the gate electrode 11 are considered co-planar even though they are slightly offset or overlapped within a certain degree of precision without deviating the present invention's intention.

The TFT 1 further includes a first ohmic contact layer 16 and a second ohmic contact layer 17, both disposed on a surface of the gate insulation layer 12 away from the gate electrode 11. The first ohmic contact layer 16 adjoins the first lateral surface 131 and is electrically connected to the source electrode 14. The second ohmic contact layer 17 adjoins the second lateral surface 132 and is electrically connected to the drain electrode 15.

The first and second ohmic contact layers 16 and 17 are metal oxide conductors. The first ohmic contact layer 16 is disposed between the source electrode 14 and the active layer 13, effectively reducing contact resistance between the source electrode 14 and the active layer 13, enhancing electronic mobility, and achieving superior conduction between the source electrode 14 and the active layer 13. The second ohmic contact layer 17 is disposed between the drain electrode 15 and the active layer 13, effectively reducing contact resistance between the drain electrode 15 and the active layer 13, enhancing electronic mobility, and achieving superior conduction between the drain electrode 15 and the active layer 13.

The TFT 1 of the present embodiment arranges the first lateral surfaces 131 and 111 of the active layer 13 and the gate electrode 11 to be co-planar, and the second lateral surfaces 132 and 112 of the active layer 13 and the gate electrode 11 to be co-planar. Then the first ohmic contact layer 16 adjoins the first lateral surface 131 of the active layer, and the second ohmic contact layer 17 adjoins the second lateral surface 132 of the active layer 13. Therefore, the first ohmic contact layer 16 is not overlapped with the gate electrode 11, and the second ohmic contact layer 17 is not overlapped with the gate electrode 11. The parasitic capacitance between the first ohmic contact layer 16 and the gate electrode 11, and between the second ohmic contact layer 17 and the gate electrode 11 is effectively reduced.

The TFT 1 further includes a protection layer 18 and a pixel electrode 19. The protection layer 18 covers the active layer 13, the source electrode 14, and the drain electrode 15. The protection layer 18 has a via 180 to expose a portion of the drain electrode 15. The pixel electrode 19 is disposed on the protection layer 18 and electrically connects the drain electrode 15 through the via 180.

Preferably, the protection layer 18 is integrally formed. That is, the protection layer 18 is first worked out in a single piece, and then patterned to obtain the via 180. In this way, the process is simplified and the protection layer 18 is ensured to have consistent technical property.

As the protection layer 18 covers the active layer 13, the source electrode 14, and the drain electrode 15, the protection layer 18 would suffer less stress. Therefore, bending TFT 1 would not easily cause cracks on the protection layer 18. The other layers of the TFT 1 is as such well protected, further enhancing the TFT 1's performance.

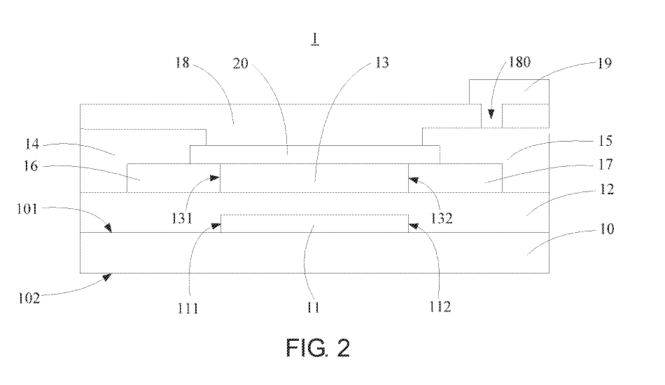

FIG. 2 is a structural schematic diagram showing a TFT according to a second embodiment of the present invention. As illustrated, the TFT of the present embodiment has basically an identical structure as that of the previous embodiment, and identical elements of these embodiments provide identical functions. Their difference lies in the present embodiment further includes an etch stopper layer 20 disposed on a surface of the active layer 13 away from the gate insulation layer 12.

The etch stopper layer 20 covers the active layer 13 so as to protect the active layer 13 from being etched during the etching formation of the source electrode and the drain electrode, thereby preserving the electrical properties of the active layer 13.

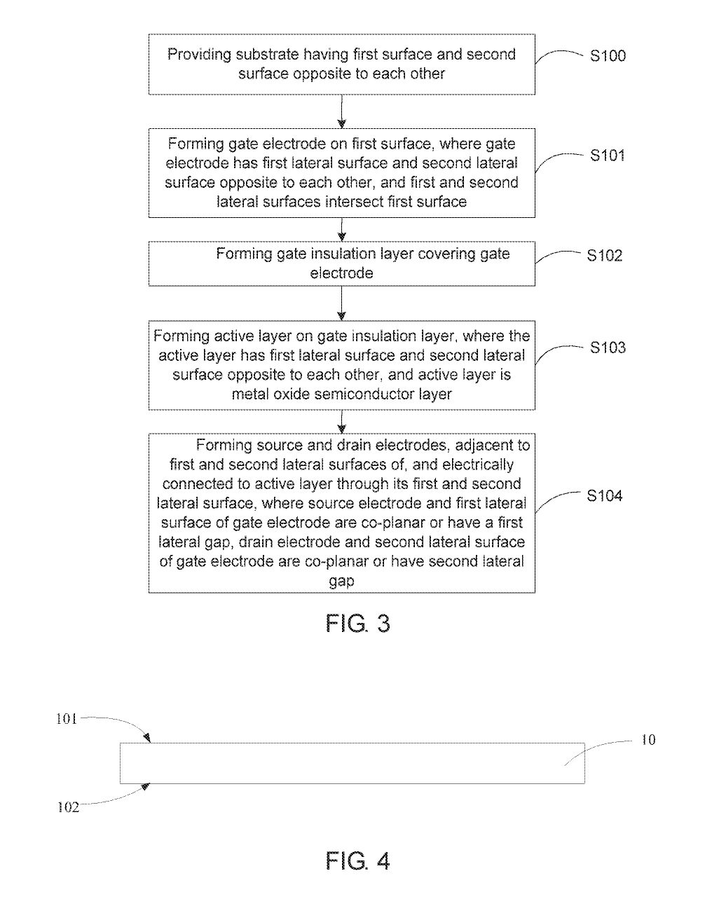

The present invention also teaches a TFT manufacturing method whose flow is shown in FIG. 3. As illustrated, the manufacturing method includes the following steps.

S100: providing a substrate 10 having first surface 101 and a second surface 102 opposite to each other, as shown in FIG. 4.

The substrate 10 is a transparent substrate, such as a glass substrate, a plastic substrate, etc. The substrate 10 may also be a flexible substrate.

“Opposite” means that they mutually face each other. That is, the first surface 101 and the second surface 102 oppositely face each other.

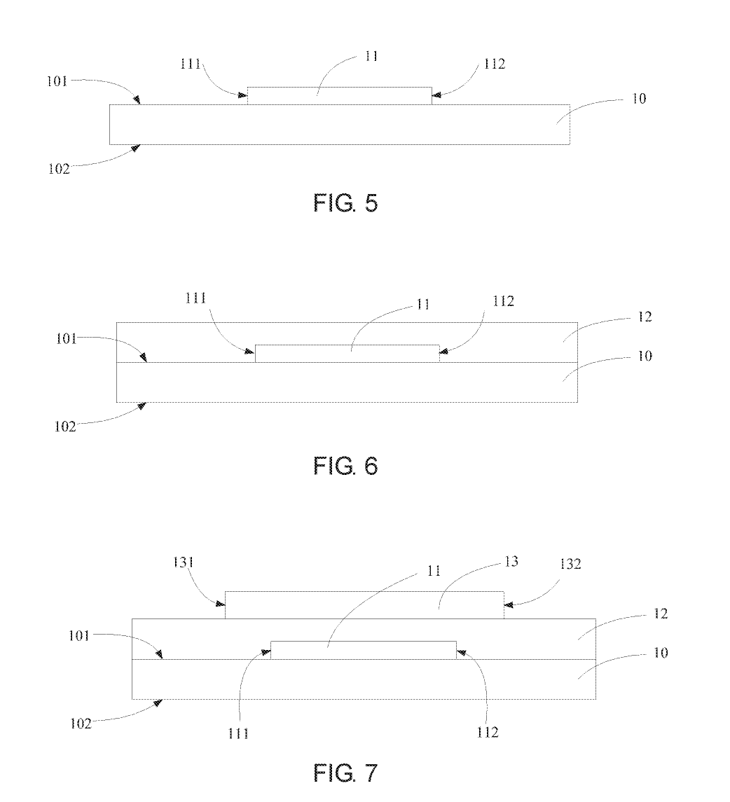

S101: forming a gate electrode 11 on the first surface 101, where the gate electrode 11 has a first lateral surface 111 and a second lateral surface 112 opposite to each other, and the first and second lateral surfaces 111 and 112 intersect the first surface 101, as illustrated in FIG. 5.

“Intersect” means that two surfaces have a common intersecting line, which may be a straight line or a curved line. In other words, the first and second lateral surfaces 111 and 112 have common intersecting lines with the first surface 101, respectively.

S102: forming a gate insulation layer 12 covering the gate electrode 11, as shown in FIG. 6.

The gate insulation layer 12 is made of silicon oxide or silicon nitride, but is not limited as such.

S103: forming an active layer 13 on the gate insulation layer 12, where the active layer 13 has a first lateral surface 131 and a second lateral surface 132 opposite to each other, and the active layer 13 is a metal oxide semiconductor layer, as shown in FIG. 7.

The active layer 13 is a metal oxide semiconductor layer. For example, the active layer 13 is an indium gallium zinc oxide (IGZO) layer but the present invention is not limited as such.

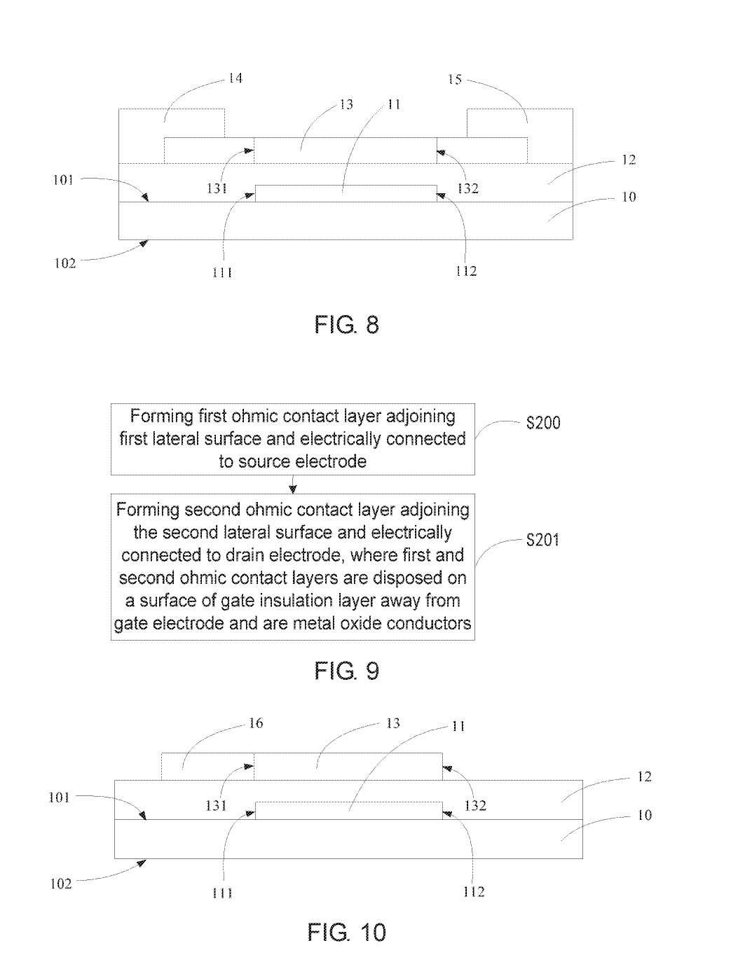

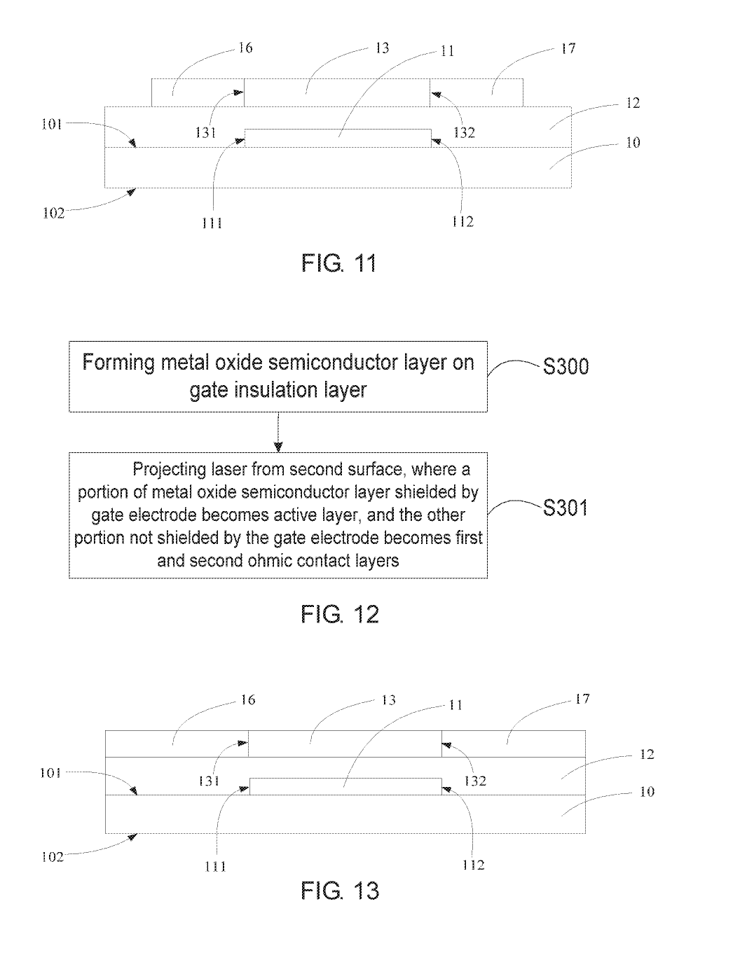

S104: forming a source electrode 14 and a drain electrode 15, where the source electrode 14 is disposed adjacent to the first lateral surface 131 of the active layer 13, and is electrically connected to the active layer 13 through its first lateral surface 131, the source electrode 14 and the first lateral surface 111 of the gate electrode 11 are co-planar or have a first lateral gap in between, the drain electrode 15 is disposed adjacent to the second lateral surface 132 of the active layer 13, and is electrically connected to the active layer 13 through its second lateral surface 132. The drain electrode 15 and the second lateral surface 112 of the gate electrode 11 are co-planar or have a second lateral gap in between, as shown in FIG. 8.

It is understandable that, considering manufacturing tolerance, the source electrode 14 and the first lateral surface 111 are considered co-planar even though they are slightly offset or overlapped within a certain degree of precision without deviating the present invention's intention.

Similarly, it is understandable that, considering manufacturing tolerance, the drain electrode 15 and the second lateral surface 112 are considered co-planar even though they are slightly offset or overlapped within a certain degree of precision without deviating the present invention's intention.

With the source electrode 14 and the first lateral surface 111 being co-planar or having the first lateral gap in between, and the drain electrode 15 and the second lateral surface 112 being co-planar or having the second lateral gap in between, gaps would be reserved between the gate electrode 11 and the source electrode 14, and between the gate electrode 11 and the drain electrode 15, respectively, thereby reducing the parasitic capacitance between the gate and source electrodes 11 and 14, and between the gate and drain electrodes 11 and 15.

FIG. 9 is a flow diagram showing additional steps of the TFT manufacturing method of FIG. 3. As illustrated, the manufacturing method further includes the following steps.

S200: forming a first ohmic contact layer 16 adjoining the first lateral surface 131 and electrically connected to the source electrode 14, as shown in FIG. 10.

S201: forming a second ohmic contact layer 17 adjoining the second lateral surface 132 and electrically connected to the drain electrode 15, where both the first and second ohmic contact layers 16 and 17 are disposed on a surface of the gate insulation layer 12 away from the gate electrode 11, and are metal oxide conductors,

The first and second ohmic contact layers 16 and 17 are disposed between the source electrode 14 and the active layer 13, and between the drain electrode 15 and the active layer 13, enhancing electronic mobility, and achieving superior conduction between the source electrode 14 and the active layer 13, and between drain electrode 15 and the active layer 13.

FIG. 12 is a flow diagram showing additional steps of the TFT manufacturing method of FIG. 3. As illustrated, the manufacturing method may include the following steps for integrally forming the active layer and the first and second ohmic contact layers.

S300: forming a metal oxide semiconductor layer on the gate insulation layer 12.

S301: projecting laser from the second surface 102, where a portion of the metal oxide semiconductor layer shielded by the gate electrode 11 becomes the active layer 13, and the other portion of the metal oxide semiconductor layer not shielded by the gate electrode 11 becomes the first and second ohmic contact layers 16 and 17, as shown in FIG. 13.

Other than laser, other light source such as infra-red light may also be applied. A planar light source providing straight or nearly straight light beams is also possible. The present invention does not provide specific constraints.

The active layer 13 is a metal oxide semiconductor layer. For example, the active layer 13 is an indium gallium zinc oxide (IGZO) layer but the present invention is not limited as such. Metal oxide semiconductor material is sensitive to light. Its resistance is reduced as the light power is increased. The metal oxide semiconductor material then may become a conductor material after being exposed to light.

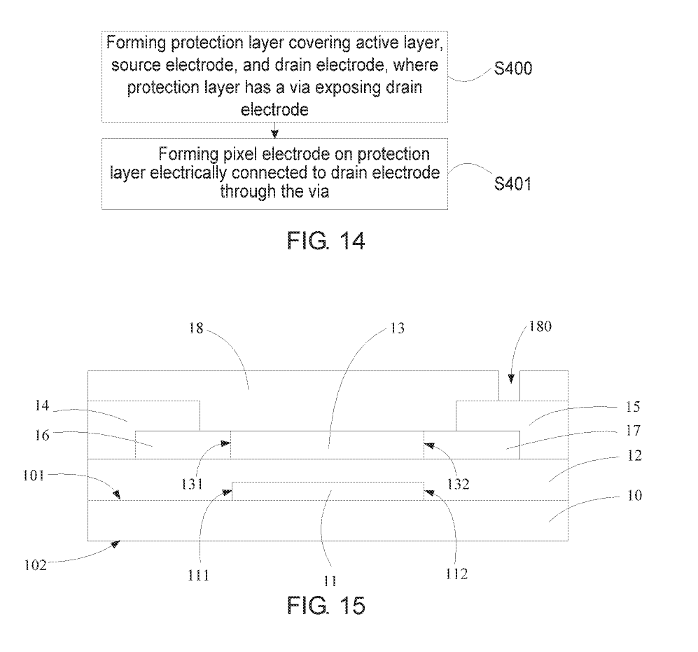

FIG. 14 is a flow diagram showing additional steps of the TFT manufacturing method of FIG. 3. As illustrated, the manufacturing method further includes the following steps.

S400: forming a protection layer 18 covering the active layer 13, the source electrode 14, and the drain electrode 15, where the protection layer 18 has a via 180 exposing a portion of the drain electrode 15, as shown in FIG. 15.

Preferably, the protection layer 18 is integrally formed. That is, the protection layer 18 is first worked out in a single piece, and then patterned to obtain the via 180. In this way, the process is simplified and the protection layer 18 is ensured to have consistent technical property.

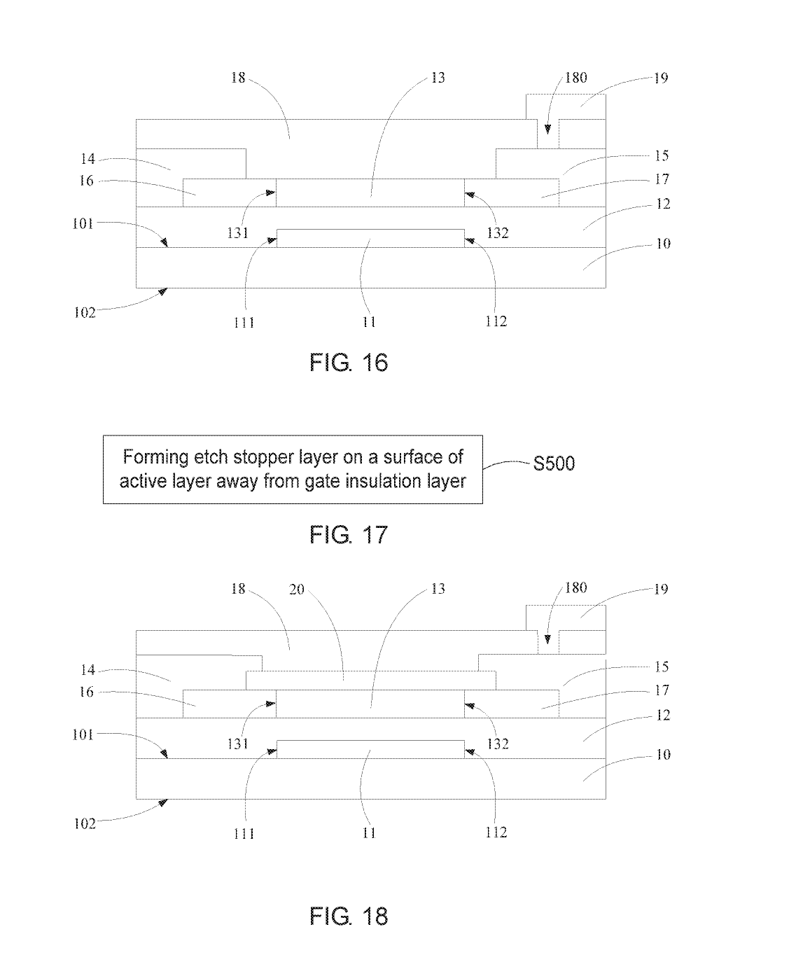

S401: forming a pixel electrode 19 on the protection layer 18 electrically connected to the drain electrode 15 through the via 180, as shown in FIG. 16.

FIG. 17 is a flow diagram showing additional steps of the TFT manufacturing method of FIG. 3. As illustrated, the manufacturing method further includes the following steps.

S500: forming an etch stopper layer 20 on a surface of the active layer 13 away from the gate insulation layer 12.

The etch stopper layer 20 covers the active layer 13 so as to protect the active layer 13 from being etched during the etching formation of the source electrode and the drain electrode, thereby preserving the electrical properties of the active layer 13.

The TFT 1 of the present invention arranges the source electrode 14 to have a first lateral gap from or to be co-planar with the first lateral surface 111 of the gate electrode 11, and arranges the drain electrode 15 to have a second lateral gap from or to be co-planar with the second lateral surface 112 of the gate electrode 11. Then the source electrode 14 is not overlapped with the gate electrode 11, and the drain electrode 15 is not overlapped with the gate electrode 11. The parasitic capacitance between the source electrode 14 and the gate electrode 11, and between the drain electrode 15 and the gate electrode 11 is effectively reduced.

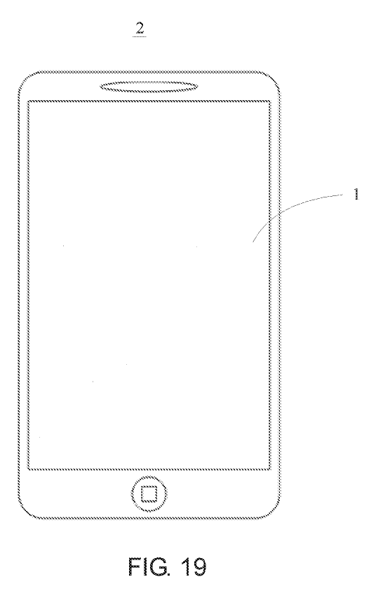

FIG. 19 is a schematic diagram showing a liquid crystal display (LCD) device according to an embodiment of the present invention. As illustrated, the LCD device 2 includes at least a TFT 1 which may be any one of the TFTs of the above embodiments. Its details are omitted here. The LCD device 2 may be, but is not limited to, electronic book, a smart phone (e.g., an Android phone, an iOS phone, a Windows Phone, etc.), a tablet computer, a palmtop computer, a notebook computer, a mobile Internet device (MID), or a wearable device.

The TFT 1 of the present invention arranges the source electrode 14 to have a first lateral gap from or to be co-planar with the first lateral surface 111 of the gate electrode 11, and arranges the drain electrode 15 to have a second lateral gap from or to be co-planar with the second lateral surface 112 of the gate electrode 11. Then the source electrode 14 is not overlapped with the gate electrode 11, and the drain electrode 15 is not overlapped with the gate electrode 11. The parasitic capacitance between the source electrode 14 and the gate electrode 11, and between the drain electrode 15 and the gate electrode 11 is effectively reduced. Therefore, the LCD device 2 including the above described TFT 1 enjoys more stable electrical properties, and has an operational life extended to a certain degree,

Above are embodiments of the present invention, which does not limit the scope of the present invention. Any equivalent amendments within the spirit and principles of the embodiment described above should be covered by the protected scope of the invention.

What is claimed is:

1. A thin film transistor (TFT), comprising a substrate, a gate electrode, a gate insulation layer, an active layer, a source electrode, and a drain electrode, wherein the substrate has a first surface and a second surface opposite to each other; the gate electrode has a first lateral surface and a second lateral surface opposite to each other; the gate electrode is disposed on the first surface of the substrate, and the first and second lateral surfaces intersect the first surface; the gate insulation layer covers the gate electrode; the active layer is disposed on a surface of the gate insulation layer away from the gate electrode; the active layer has a first lateral surface and a second lateral surface opposite to each other; the source electrode is disposed adjacent to the first lateral surface of the active layer, and is electrically connected to the active layer through its first lateral surface; the source electrode and the first lateral surface of the gate electrode are co-planar or have a first lateral gap in between; the drain electrode is disposed adjacent to the second lateral surface of the active layer, and is electrically connected to the active layer through its second lateral surface; the drain electrode and the second lateral surface of the gate electrode are co-planar or have a second lateral gap in between; and the active layer is a metal oxide semiconductor layer.

2. The TFT according to claim 1, further comprising a first ohmic contact layer and a second ohmic contact layer, both disposed on a surface of the gate insulation layer away from the gate electrode, wherein the first ohmic contact layer adjoins the first lateral surface of the active layer and is electrically connected to the source electrode; and the second ohmic contact layer adjoins the second lateral surface of the active layer and is electrically connected to the drain electrode.

3. The TFT according to claim 2, wherein the first and second ohmic contact layers are metal oxide conductors.

4. The TFT according to claim 3, wherein the first lateral surfaces of active layer and the gate electrode are co-planar; and the second lateral surfaces of the active layer and the gate electrode are co-planar.

5. The TFT according to claim 1, further comprising a protection layer and a pixel electrode, wherein the protection layer covers the active layer, the source electrode, and the drain electrode; the protection layer has a via exposing a portion of the drain electrode; and the pixel electrode is disposed on the protection layer and electrically connects the drain electrode through the via.

6. The TFT according to claim 2_{;} further comprising a protection layer and a pixel electrode, wherein the protection layer covers the active layer, the source electrode_{;} and the drain electrode; the protection layer has a via exposing a portion of the drain electrode; and the pixel electrode is disposed on the protection layer and electrically connects the drain electrode through the via.

7. The TFT according to claim 3, further comprising a protection layer and a pixel electrode_{;} wherein the protection layer covers the active layer_{;} the source electrode, and the drain electrode; the protection layer has a via exposing a portion of the drain electrode; and the pixel electrode is disposed on the protection layer and electrically connects the drain electrode through the via,

8. The TFT according to claim 4, further comprising a protection layer and a pixel electrode, wherein the protection layer covers the active layer, the source electrode, and the drain electrode; the protection layer has a via exposing a portion of the drain electrode; and the pixel electrode is disposed on the protection layer and electrically connects the drain electrode through the via.

9. A TFT manufacturing method, comprising
providing a substrate having a first surface and a second surface opposite to each other;
forming a gate electrode on the first surface, where the gate electrode has a first lateral surface and a second lateral surface opposite to each other, and the first and second lateral surfaces intersect the first surface;
forming a gate insulation layer covering the gate electrode;
forming an active layer on the gate insulation layer, where the active layer has a first lateral surface and a second lateral surface opposite to each other, and the active layer is a metal oxide semiconductor layer; and
forming a source electrode and a drain electrode, where the source electrode is disposed adjacent to the first lateral surface of the active layer, and is electrically connected to the active layer through its first lateral surface, the source electrode and the first lateral surface of the gate electrode are co-planar or have a first lateral gap in between, the drain electrode is disposed adjacent to the second lateral surface of the active layer, and is electrically connected to the active layer through its second lateral surface, and the drain electrode and the second lateral surface of the gate electrode are co-planar or have a second lateral gap in between.

10. The TFT manufacturing method according to claim 9, further comprising
forming a first ohmic contact layer adjoining the first lateral surface of the active layer and electrically connected to the source electrode; and
forming a second ohmic contact layer adjoining the second lateral surface of the active layer and electrically connected to the drain electrode, wherein both the first and second ohmic contact layers are disposed on a surface of the gate insulation layer away from the gate electrode, and are metal oxide conductors.

11. The TFT manufacturing method according to claim 10, comprising the following steps for integrally forming the active layer and the first and second ohmic contact layers
forming a metal oxide semiconductor layer on the gate insulation layer; and
projecting laser from the second surface, where a portion of the metal oxide semiconductor layer shielded by the gate electrode becomes the active layer, and the other portion of the metal oxide semiconductor layer not shielded by the gate electrode becomes the first and second ohmic contact layers.

12. The TFT manufacturing method according to claim 9, further comprising
forming a protection layer covering the active layer, the source electrode, and the drain electrode, where the protection layer has a via exposing a portion of the drain electrode; and
forming a pixel electrode on the protection layer electrically connected to the drain electrode through the via.

13. The TFT manufacturing method according to claim 10, further comprising
forming a protection layer covering the active layer, the source electrode, and the drain electrode, where the protection layer has a via exposing a portion of the drain electrode; and
forming a pixel electrode on the protection layer electrically connected to the drain electrode through the via.

14. The TFT manufacturing method according to claim 11, further comprising
forming a protection layer covering the active layer_{;} the source electrode, and the drain electrode, where the protection layer has a via exposing a portion of the drain electrode; and
forming a pixel electrode on the protection layer electrically connected to the drain electrode through the via.

15. A liquid crystal display (LCD) device, comprising a TFT, wherein the TFT comprises a substrate, a gate electrode, a gate insulation layer, an active layer, a source electrode, and a drain electrode_{;} wherein the substrate has a first surface and a second surface opposite to each other; the gate electrode has a first lateral surface and a second lateral surface opposite to each other; the gate electrode is disposed on the first surface of the substrate, and the first and second lateral surfaces intersect the first surface; the gate insulation layer covers the gate electrode; the active layer is disposed on a surface of the gate insulation layer away from the gate electrode; the active layer has a first lateral surface and a second lateral surface opposite to each other; the source electrode is disposed adjacent to the first lateral surface of the active layer, and is electrically connected to the active layer through its first lateral surface; the source electrode and the first lateral surface of the gate electrode are co-planar or have a first lateral gap in between; the drain electrode is disposed adjacent to the second lateral surface of the active layer, and is electrically connected to the active layer through its second lateral surface;
the drain electrode and the second lateral surface of the gate electrode are co-planar or have a second lateral gap in between; and the active layer is a metal oxide semiconductor layer.

16. The LCD device according to claim 15, wherein the TFT further comprises a first ohmic contact layer and a second ohmic contact layer_{;} both disposed on a surface of the gate insulation layer away from the gate electrode; the first ohmic contact layer adjoins the first lateral surface of the active layer and is electrically connected to the source electrode; and the second ohmic contact layer adjoins the second lateral surface of the active layer and is electrically connected to the drain electrode.

17. The LCD device according to claim 16, wherein the first and second ohmic contact layers are metal oxide conductors.

18. The LCD device according to claim 17, wherein the first lateral surfaces of active layer and the gate electrode are co-planar; and the second lateral surfaces of the active layer and the gate electrode are co-planar.

19. The LCD device according to claim 15, wherein the TFT further comprises a protection layer and a pixel electrode; the protection layer covers the active layer, the source electrode, and the drain electrode; the protection layer has a via exposing a portion of the drain electrode; and the pixel electrode is disposed on the protection layer and electrically connects the drain electrode through the via.

20. The LCD device according to claim 16, wherein the TFT further comprises a protection layer and a pixel electrode; the protection layer covers the active layer, the source electrode, and the drain electrode; the protection layer has a via exposing a portion of the drain electrode; and the pixel electrode is disposed on the protection layer and electrically connects the drain electrode through the via.
